(19) United States
(12) Patent Application Publication
(10) Pub. No.: US 2025/0241081 A1
(43) Pub. Date: Jul. 24, 2025

(54) SOLID-STATE IMAGING DEVICE AND ELECTRONIC DEVICE

(71) Applicant: SONY SEMICONDUCTOR SOLUTIONS CORPORATION, Kanagawa (JP)

(72) Inventors: Takashi NAKAMURA, Tokyo (JP); Akimi HIGASHI, Kagoshima (JP)

(73) Assignee: SONY SEMICONDUCTOR SOLUTIONS CORPORATION, Kanagawa (JP)

(21) Appl. No.: 18/852,635

(22) PCT Filed: Apr. 10, 2023
(86) PCT No.: PCT/JP2023/014547

§ 371 Date: Sep. 30, 2024

(30) Foreign Application Priority Data
Apr. 27, 2022 (JP) 2022-072882

(51) Int. Cl. H10F 39/00; H10F 39/18

(52) U.S. Cl. CPC H10F 39/807; H10F 39/182; H10F 39/811

(57) ABSTRACT

The present disclosure relates to a solid-state imaging device and an electronic device, which are capable of achieving a high-speed communication interface. The solid-state imaging device includes a pixel substrate on which a pixel is formed, and a control substrate, the pixel substrate and the control substrate being stacked. The pixel substrate includes a pad serving as a contact point with an external device. The control substrate includes a signal pad wiring connected to the pad, a shield wiring disposed around the signal pad wiring, and a high-resistance element connected to the shield wiring. The present disclosure is applicable to the solid-state imaging device and other devices, for example.

### TECHNICAL FIELD

The present disclosure relates to a solid-state imaging device and an electronic device, and particularly relates to a solid-state imaging device and an electronic device, which are capable of achieving a high-speed communication interface.

### BACKGROUND ART

Backside-illuminated solid-state imaging devices with a stacked structure in which a pixel substrate on which pixels are formed and a control substrate on which a control circuit that controls the pixels or performs other processing is formed are stacked have been widely used. In the backside-illuminated solid-state imaging devices with the stacked structure, there is a structure in which a pad serving as an output section that outputs a pixel signal or other signals is formed on the control substrate side, and an opening process has been performed on a portion on the pixel substrate side over the pad. In such a structure, since the pad is positioned at the deeper position as viewed from the pixel substrate side, wire bonding to be formed on the pad is required to be accurately carried out, which causes deterioration in assembly quality.

Therefore, Patent Document 1 has proposed a structure in which a pad is formed in a wiring layer that is an uppermost layer of a pixel substrate. In addition, Patent Document 2 has proposed a technology in which, in a case where a pad is formed in a wiring layer that is an uppermost layer of a pixel substrate, the pad of the pixel substrate is connected to a wiring on a control substrate side to improve quality related to the formation of color filters, microlenses, and other components, and a variation in device characteristics or other changes during a heat treatment.

### CITATION LIST

### Patent Document

Patent Document 1: Japanese Patent Application Laid-Open No. 2012-235126
Patent Document 2: Japanese Patent Application Laid-Open No. 2021-153335

### SUMMARY OF THE INVENTION

### Problems to be Solved by the Invention

However, in a case where the pad of the pixel substrate is connected to the wiring on the control substrate side, there is a concern that pad capacitance increases. In response to an increase in the number of pixels for a solid-state imaging device and an increase in demand for moving image performance, a baud rate of a communication interface mounted in the solid-state imaging device is increasing year by year, and pad capacitance is one of factors that restrict the increase in the rate.

The present disclosure has been made in view of such a situation, and an object thereof is to achieve a high-speed communication interface.

### Solutions to Problems

A solid-state imaging device according to a first aspect of the present disclosure includes a pixel substrate on which a pixel is formed and a control substrate, in which the pixel substrate and the control substrate are stacked, the pixel substrate includes a pad serving as a contact point with an external device, and the control substrate includes a signal pad wiring connected to the pad, a shield wiring disposed around the signal pad wiring, and a high-resistance element connected to the shield wiring.

An electronic device according to a second aspect of the present disclosure is provided with a solid-state imaging device that includes a pixel substrate on which a pixel is formed, and a control substrate, in which the pixel substrate and the control substrate are stacked, the pixel substrate includes a pad serving as a contact point with an external device, and the control substrate includes a signal pad wiring connected to the pad, a shield wiring disposed around the signal pad wiring, and a high-resistance element connected to the shield wiring.

According to the first and second aspects of the present disclosure, the pixel substrate on which the pixel is formed and the control substrate are stacked, the pixel substrate is provided with the pad serving as the contact point with the external device, and the control substrate is provided with the signal pad wiring connected to the pad, the shield wiring disposed around the signal pad wiring, and the high-resistance element connected to the shield wiring.

The solid-state imaging device or the electronic device may be an independent device or a module incorporated in another device.

### BRIEF DESCRIPTION OF DRAWINGS

FIG. 1 is a diagram illustrating a schematic configuration of a solid-state imaging device to which the technology of the present disclosure is applied.

FIG. 2 is a schematic plan view of a pixel substrate and a control substrate.

FIG. 3 is a cross-sectional view schematically illustrating a stacked structure of the pixel substrate and the control substrate.

FIG. 4 is a cross-sectional view related to a signal pad wiring of the control substrate.

FIG. 5 is a perspective view related to the signal pad wiring of the control substrate.

FIG. 6 is a diagram illustrating an effect related to the signal pad wiring of the control substrate.

FIG. 7 is a diagram illustrating an effect related to the signal pad wiring of the control substrate.

FIG. 8 is a plan view illustrating wiring pattern examples of the signal pad wiring.

FIG. 9 is a plan view illustrating shield wirings around signal pad wirings.

FIG. 10 is a plan view illustrating shield wirings around the signal pad wirings.

FIG. 11 is a plan view illustrating wiring pattern examples of a power supply or ground pad wiring.

FIG. 12 is a diagram illustrating configuration examples of a high-resistance element.

FIG. 13 is a diagram illustrating configuration examples of the high-resistance element.

FIG. 14 is a diagram illustrating a modification of a potential supplied to the shield wiring.

FIG. 15 is a diagram illustrating a modification of a potential supplied to the shield wiring.

FIG. 16 is a diagram illustrating a modification of a potential supplied to the shield wiring.

FIG. 17 is a diagram illustrating a modification of a potential supplied to the shield wiring.

FIG. 18 is a diagram illustrating a usage example of an image sensor.

FIG. 19 is a block diagram illustrating a configuration example of an imaging device as an electronic device to which the technology of the present disclosure is applied.

FIG. 20 is a block diagram illustrating an exemplary schematic configuration of a vehicle control system.

FIG. 21 is a diagram of assistance in explaining an example of installation positions of an outside-vehicle information detecting section and an imaging section.

### MODE FOR CARRYING OUT THE INVENTION

Hereinafter, modes for carrying out the technology of the present disclosure (which will be hereinafter referred to as embodiments) will be described with reference to the accompanying drawings. The description will be given in the following order.
1. Schematic configuration example of solid-state imaging device
2. Schematic plan view of pixel substrate and control substrate
3. Cross-sectional view of pixel substrate and control substrate
4. Cross-sectional view of signal pad wiring structure
5. Effect of signal pad wiring structure
6. Wiring pattern examples of pad connection wiring on control substrate side
7. Wiring pattern examples of pad connection wiring for power-supply voltage and ground
8. Configuration example of high-resistance element
9. Modification of potential supplied to shield wiring
10. Usage example of image sensor
11. Application example for electronic device
12. Practical example for mobile body

Note that, in the drawings referred to in the following description, the same or similar parts are denoted by the same or similar reference signs, and the description thereof will not be repeated as appropriate. The drawings are schematic, and the relationship between the thickness and the plane dimension, the ratio of the thickness of each layer, and other points are different from the actual ones. In addition, the drawings may include parts having different dimensional relationships and ratios.

In addition, definition of directions such as upward and downward directions, and the like in the following description is merely the definition for convenience of description, and does not limit the technical idea of the present disclosure. For example, when an object is rotated by 90° to be observed, the upper and lower sides are changed as the left and right sides, and when the object is rotated by 180°, the upper and lower sides are reversed.

### <1. Schematic Configuration Example of Solid-State Imaging Device>

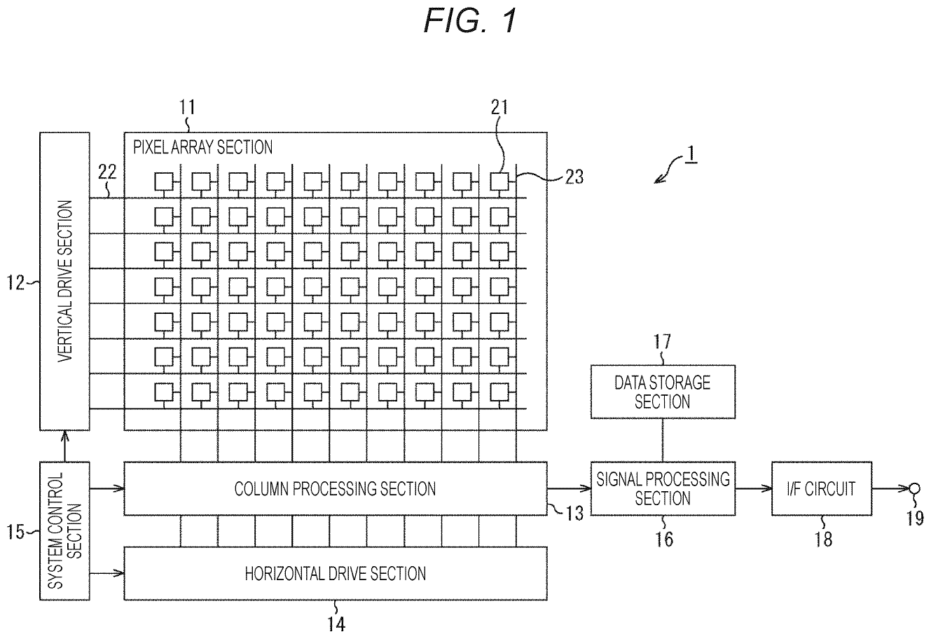

FIG. 1 is a diagram illustrating a schematic configuration of a solid-state imaging device to which the technology of the present disclosure is applied.

A solid-state imaging device 1 in FIG. 1 illustrates a configuration of a CMOS image sensor which is a type of solid-state imaging device of an X-Y address system, for example. The CMOS image sensor is an image sensor manufactured by applying or partially using a CMOS process.

The solid-state imaging device 1 includes a pixel array section 11 and peripheral circuit sections. The peripheral circuit sections include, for example, a vertical drive section 12, a column processing section 13, a horizontal drive section 14, and a system control section 15.

The solid-state imaging device 1 further includes a signal processing section 16, a data storage section 17, and an I/F circuit 18. At least one of the signal processing section 16, the data storage section 17, or the I/F circuit 18 is disposed over a substrate different from the substrate on which the pixel array section 11 is formed.

The pixel array section 11 has a configuration in which pixels 21 each of which has a photoelectric conversion section that generates and accumulates photocharges according to the amount of received light are two-dimensionally arranged in a matrix in the row direction and the column direction. Here, the row direction refers to a pixel row of the pixel array section 11, that is, an array direction in the horizontal direction, and the column direction refers to a pixel column of the pixel array section 11, that is, an array direction in the vertical direction.

Each of the pixels 21 includes a photodiode serving as a photoelectric conversion section and a plurality of pixel transistors (what is called MOS transistors). The plurality of pixel transistors includes four transistors that are a transfer transistor, a selection transistor, a reset transistor, and an amplification transistor, for example.

In the pixel array section 11, pixel drive wirings 22 serving as row signal lines are disposed, one for each pixel row, along the row direction and vertical signal lines 23 serving as column signal lines are disposed, one for each pixel column, along the column direction. Each of the pixel drive wirings 22 transmits a drive signal for driving when a signal is read from each of the pixels 21. In FIG. 1, each of the pixel drive wirings 22 is illustrated as a single piece of wiring, but not limited to the single piece of wiring. One end of each of the pixel drive wirings 22 is connected to an output terminal corresponding to each row of the vertical drive section 12.

The vertical drive section 12 includes a shift register, an address decoder, and other components and drives the individual pixels 21 in the pixel array section 11 at the same time for all the pixels, row by row, or other ways. The vertical drive section 12 constitutes a drive section that controls the operation of each of the pixels 21 in the pixel array section 11 together with the system control section 15. Although a specific configuration of the vertical drive section 12 is not illustrated, the vertical drive section generally includes two scanning systems of a reading scanning system and a sweeping scanning system.

In order to read a signal from each of the pixels 21, the reading scanning system sequentially selects and scans the pixels 21 of the pixel array section 11 row by row. The signal read from each of the pixels 21 is an analog signal. The sweeping scanning system performs sweep scanning on a read row on which the read scanning is to be performed by the reading scanning system earlier than the read scanning by an exposure time.

The sweep scanning by the sweeping scanning system allows unnecessary photocharges to be swept out from the photoelectric conversion section of each of the pixels 21 in the read row, thereby resetting the photoelectric conversion section of each of the pixels 21. Then, by sweeping out (resetting) unnecessary photocharges by the sweeping scanning system, a so-called electronic shutter operation is performed. Here, the electronic shutter operation refers to operation of discharging the photocharges of the photoelectric conversion section and newly starting exposure (starting accumulation of photocharges).

The signal read by the read operation of the reading scanning system corresponds to the amount of the received light after the immediately preceding read operation or electronic shutter operation. Then, the period from the read timing by the immediately preceding read operation or the sweep timing by the electronic shutter operation to the read timing by the current read operation is the exposure period in the pixels 21.

The signal output from each of the pixels 21 in the pixel row selectively scanned by the vertical drive section 12 is input to the column processing section 13 through each of the vertical signal lines 23 for each pixel column. The column processing section 13 performs predetermined signal processing on the signal output from each pixel 21 in the selected row through the vertical signal line 23 for each pixel column of the pixel array section 11, and temporarily holds the pixel signal after the signal processing.

Specifically, the column processing section 13 performs, as signal processing, at least noise removal processing, for example, correlated double sampling (CDS) processing or double data sampling (DDS) processing. For example, in the CDS processing, fixed pattern noise unique to the pixel, such as reset noise or threshold variation of an amplification transistor in the pixel, is removed. The column processing section 13 may have, for example, an analog-digital (AD) conversion function in addition to the noise removal processing, and convert an analog pixel signal into a digital signal and output the digital signal.

The horizontal drive section 14 includes a shift register, an address decoder, and other components, and sequentially selects a unit circuit corresponding to the pixel column in the column processing section 13. When the selective scanning is performed by the horizontal drive section 14, the pixel signal subjected to the signal processing for every unit circuit in the column processing section 13 is sequentially output.

The system control section 15 includes a timing generator that generates various timing signals and other components, and performs drive control of the vertical drive section 12, the column processing section 13, the horizontal drive section 14, and other sections on the basis of various timings generated by the timing generator.

The signal processing section 16 has at least an arithmetic processing function, and performs various signal processing such as arithmetic processing on the pixel signals output from the column processing section 13. The data storage section 17 temporarily stores data necessary for signal processing in the signal processing section 16. The pixel signal on which the signal processing has been completed in the signal processing section 16 is supplied to the I/F circuit 18.

The I/F circuit 18 converts the pixel signal supplied from the signal processing section 16 into a predetermined format such as the mobile industry processor interface (MIPI) standard, for example, and outputs the converted signal to an external device via the output section 19.

The solid-state imaging device 1 configured as described above has a stacked structure in which a pixel substrate on which the pixels 21 are formed and a control substrate on which a control circuit that controls the pixels 21 or performs signal processing and other processing is formed are stacked.

### <2. Schematic Plan View of Pixel Substrate and Control Substrate>

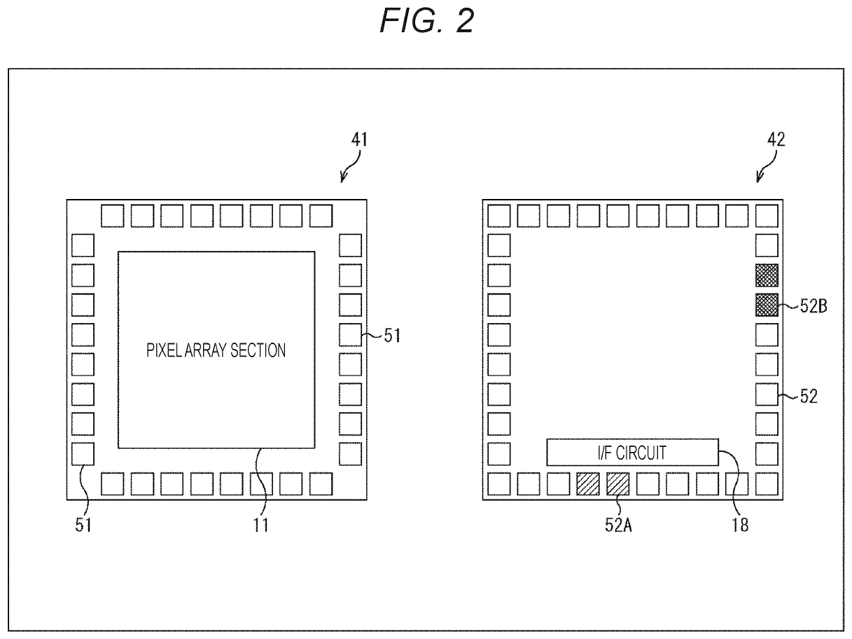

FIG. 2 is a schematic plan view of a pixel substrate 41 on which the pixels 21 are formed and a control substrate 42 on which a control circuit or a signal processing circuit for the pixels 21 is formed.

In the pixel substrate 41, the pixel array section 11 is formed at the substrate center portion of the chip-size. In addition, a plurality of pads 51 each of which serves as a contact point with an external device is formed on the outer peripheral portion of the substrate to surround the outside of the pixel array section 11. Each of the pads 51 on the pixel substrate 41 includes the output section 19 in FIG. 1 and is electrically connected to the external device by wire bonding or other methods. The pads 51 of the pixel substrate 41 include a signal pad 51 to which a signal such as a pixel signal or a control signal is supplied, and a power supply or ground pad 51 to which a power-supply voltage or a ground is supplied. The shape of the pads 51 is not different between the signal application and the power supply or ground application.

On the other hand, the control substrate 42 is provide with the I/F circuit 18 and a plurality of pad wirings 52. In addition, although not illustrated, the control substrate 42 may be provided with, for example, the signal processing section 16, the system control section 15, and other sections.

The pad wirings 52 of the control substrate 42 are formed at positions corresponding to the pads 51 of the pixel substrate 41, and are wirings on the control substrate 42 side, each wiring being electrically connected to each pad 51 at the same planar position. The pad wirings 52 include a pad wiring 52A (hereinafter, referred to as a signal pad wiring 52A) that is electrically connected to the signal pad 51 of the pixel substrate 41 and a pad wiring 52B (hereinafter, referred to as a power supply or ground pad wiring 52B) that is electrically connected to the power supply or ground pad 51 of the pixel substrate 41. For example, the signal pad wiring 52A and the power supply or ground pad wiring 52B has different wiring pattern areas from each other.

### <3. Cross-Sectional View of Pixel Substrate and Control Substrate>

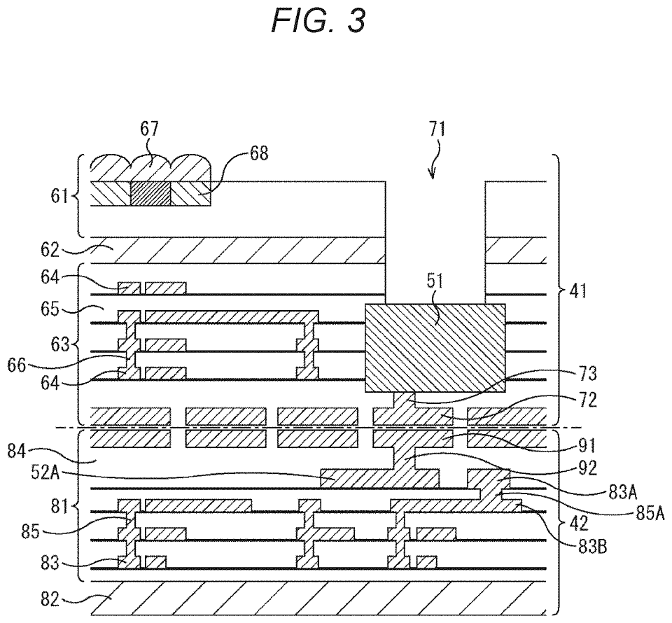

FIG. 3 is a cross-sectional view schematically illustrating a structure in which the pixel substrate 41 and the control substrate 42 are stacked, and is a cross-sectional view of a portion corresponding to the signal pad wiring 52A.

In FIG. 3, the pixel substrate 41 of the upper side and the control substrate 42 of the lower side are bonded at an interface formed therebetween, the interface being indicated by one-dot chain line.

The pixel substrate 41 includes a light-condensing layer 61, a semiconductor substrate 62, and a wiring layer 63, which are stacked in this order from the top. Therefore, the light-condensing layer 61 and the wiring layer 63 are disposed on opposite sides to each other, with the semiconductor substrate 62 interposed therebetween (with respect to the semiconductor substrate 62). The wiring layer 63 is formed on the front surface side of the semiconductor substrate 62, and the light-condensing layer 61 is formed on the back surface side.

The light-condensing layer 61 includes an on-chip microlens 67, a color filter 68, and other components. Light incident from a subject onto an upper surface (incident surface) of the light-condensing layer 61 is condensed in a photodiode (not illustrated) that is formed in the semiconductor substrate 62 by the on-chip microlens 67.

The semiconductor substrate 62 includes, for example, a silicon substrate containing silicon (Si) as a semiconductor. Note that, a material of the semiconductor substrate 62 may be, for example, a Group IV semiconductor such as Ge or may be a Group III-V semiconductor such as GaAs, InP, or InGaAs, in addition to Si described above. Although not illustrated, semiconductor devices, such as a photodiode of each pixel 21, a transfer gate, a charge-voltage converter (FD), a reset gate, an amplification transistor, and a selection transistor, are formed in the semiconductor substrate 62.

In the wiring layer 63, multi-layer wirings 64 and an interlayer insulating film 65 are formed. Each wiring 64 is connected to an upper-layer wiring 64 or a lower-layer wiring 64 via a via 66 in a predetermined region. The wirings 64 and the via 66 are formed using a metal material such as Cu, Al, or other metal materials, for example.

In addition, the pad 51 for external connection is formed in the wiring layer 63. In this example, the pad 51 is formed to have a thickness substantially equivalent to the height from a second-layer wiring 64 to a fourth-layer wiring 64 constituting the wiring layer 63. A through-hole 71 penetrating the light-condensing layer 61 and the semiconductor substrate 62 is formed above the pad 51. A part of a surface (hereinafter, referred to as a connection surface) of the pad 51 where a wire bond ball is to be formed is exposed by the formation of the through-hole 71.

A via 73 is connected to a surface opposite to the connection surface of the pad 51, and the pad 51 is connected to a pad 72 for bonding to the control substrate 42 via the via 73. The pad 72 contains Cu, for example. The pad 72 is connected to a pad 91 of a wiring layer 81 of the control substrate 42 by Cu—Cu bonding.

The control substrate 42 includes the wiring layer 81 and a semiconductor substrate 82, which are stacked in this order from the top. The wiring layer 81 of the control substrate 42 is formed at the wiring layer 63 side of the pixel substrate 41, and the wiring layer 63 of the pixel substrate 41 and the wiring layer 81 of the control substrate 42 are in contact with each other.

In the wiring layer 81, multi-layer wirings 83 and an interlayer insulating film 84 are formed. Each wiring 83 is connected to an upper-layer wiring 83 or a lower-layer wiring 83 via a via 85 in a predetermined region. The wirings 83 and the via 85 are formed using a metal material such as Cu, Al, or other metal materials, for example.

A pad 91 for bonding to the pixel substrate 41 is formed on the upper end of the wiring layer 81. The pad 91 contains Cu, for example. In FIG. 3, although a gap is provided for easy understanding of the drawing, the lower surface of the pad 72 of the pixel substrate 41 and the upper surface of the pad 91 of the control substrate 42 are connected by Cu—Cu bonding.

The pad 91 on the control substrate 42 side, which is Cu—Cu bonded to the pad 72 on the pixel substrate 41 side, is connected to the signal pad wiring 52A at an uppermost layer level in the wiring layer 81 via the via 92. A wiring 83A is provided at a predetermined position of the same layer level as the signal pad wiring 52A, and the wiring 83A is connected to a wiring 83B below the signal pad wiring 52A via a via 85A.

The semiconductor substrate 82 is formed using, for example, a silicon substrate, but it is similar to the semiconductor substrate 62 described above in that a material other than silicon may be used.

The solid-state imaging device 1 in which the pixel substrate 41 and the control substrate 42 are stacked as described above includes a backside-illuminated MOS solid-state imaging device in which light is incident from a rear surface side of the semiconductor substrate 62.

In the solid-state imaging device 1, the pad 51 on the pixel substrate 41 side, which outputs a pixel signal as an output signal, is electrically connected to the signal pad wiring 52A on the control substrate 42 side via the via 73, the pad 72, the pad 91, and the via 92. In the wiring layer 81 on the control substrate 42 side, the signal pad wiring 52A, the wiring 83A, the wiring 83B, and other wirings employ a structure on which the influence of capacitance is reduced in terms of electrical characteristics, thereby achieving a high-speed communication interface and a broadband. Hereinafter, a wiring structure in the wiring layer 81 on the control substrate 42 side, which has achieved the high-speed communication interface and broadband, will be described in detail.

### <4. Cross-Sectional View of Signal Pad Wiring Structure>

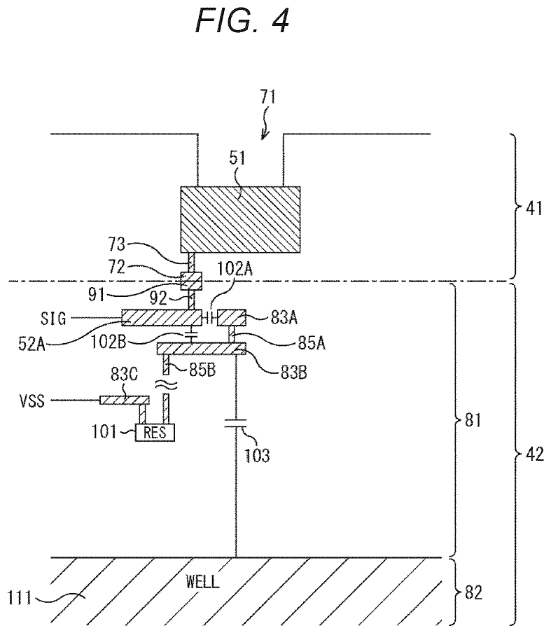

FIG. 4 is a cross-sectional view illustrating details of a pad wiring structure in the wiring layer 81 on the control substrate 42 side, the wiring layer 81 being connected to the signal pad 51 of the pixel substrate 41 in FIG. 3.

The pad 51 of the pixel substrate 41 is connected to the signal pad wiring 52A of the control substrate 42 via the via 73, the pad 72, the pad 91, and the via 92. An output signal SIG is supplied to the signal pad wiring 52A, and the output signal SIG is output from the pad 51 of the pixel substrate 41 to the external device via the pad 91, the pad 72, and other components.

The wiring 83A formed at the same layer level as the signal pad wiring 52A is connected to the wiring 83B below the signal pad wiring 52A via the via 85A, and the wiring 83B below the signal pad wiring 52A is connected to a high-resistance element 101 and a wiring 83C in the wiring layer 81 via a via 85B and other parts. A VSS potential (for example, GND) is supplied to the wiring 83C. The VSS potential is also supplied to the wirings 83A and 83B via the high-resistance element 101, and the wirings 83A and 83B constitute a shield wiring.

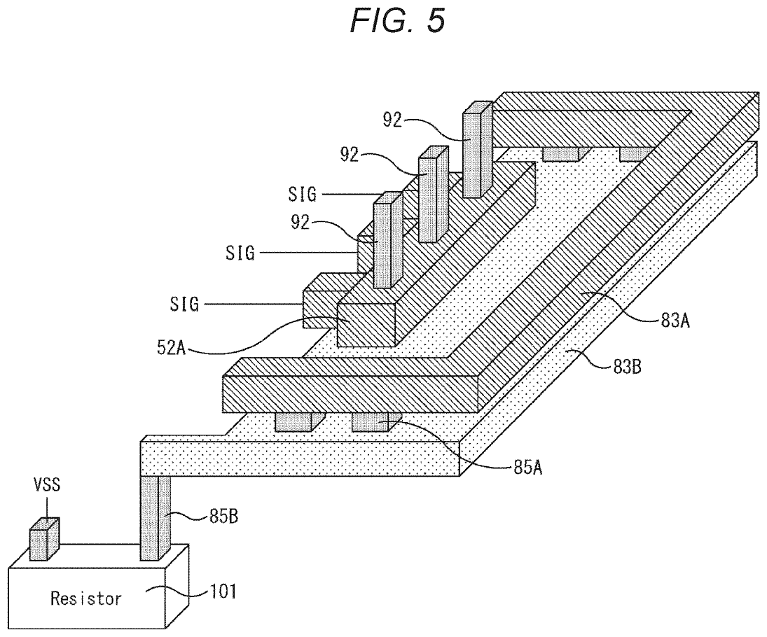

FIG. 5 is a perspective view illustrating a specific arrangement example of the signal pad wiring 52A to which the output signal SIG is input and the wirings 83A and 83B and other components formed as the shield wiring around the signal pad wiring. Note that, in FIG. 5, the patterns of the wirings 83A and 83B and other components are changed with those in FIG. 4 in order to make the drawing easy to understand.

The signal pad wiring 52A to which the output signal SIG is input is formed to have a smaller plane area than the pad 51 of the pixel substrate 41 within a range that allows a current value of the output signal SIG. In the example of FIG. 5, the signal pad wiring 52A includes the three comb-teeth shape, and the three vias 92 for the connection to the pad 91 above the signal pad wiring 52A (FIG. 4) are also formed; however, the number of comb-teeth and wiring area may be formed corresponding to the current value of the output signal SIG, and are not limited to this example.

The wiring 83A is disposed at the same layer level as the signal pad wiring 52A to surround the signal pad wiring 52A, and the wiring 83B is formed at a position to overlap with the signal pad wiring 52A and the wiring 83A in plan view. The wiring 83B is connected to the high-resistance element 101 via one or more vias (including the via 85B).

The pad 51 of the pixel substrate 41 in FIG. 4 is formed to have a thickness and an area to withstand the stress of the wire bond ball. Since the stress resistance is sufficiently provided by the pad 51 of the pixel substrate 41, the signal pad wiring 52A on the control substrate 42 side, which is connected to the pad 51, is required to be provided with only the current resistance of the output signal SIG. Thus, the signal pad wiring 52A can be formed as the minimum plane area that allows the current value of the output signal SIG.

Although capacitances 102A and 102B, which function as a pad coupling capacitance, are generated between the adjacent wirings 83A and 83B respectively disposed at the same layer level as the signal pad wiring 52A and below the signal pad wiring 52A, the pad coupling capacitance can be reduced by forming the signal pad wiring 52A with the minimum area. In addition, shield capacitances (capacitances 102A and 102B) can be invalidated by supplying the VSS potential to the wirings 83A and 83B via the high-resistance element 101. Although a parasitic capacitance 103 generated between the upper and lower wirings 83 is generated between the wiring 83B and a well region 111 (or a P sub-substrate region) of the semiconductor substrate 82, the parasitic capacitance 103 can also be invalidated by supplying the VSS potential to the wiring 83B via the high-resistance element 101.

### <5. Effect of Signal Pad Wiring Structure>

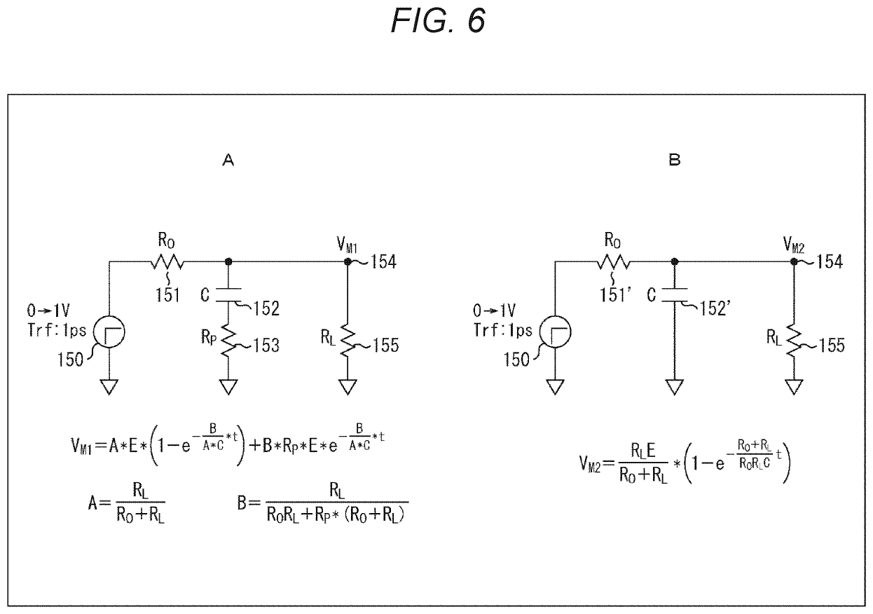

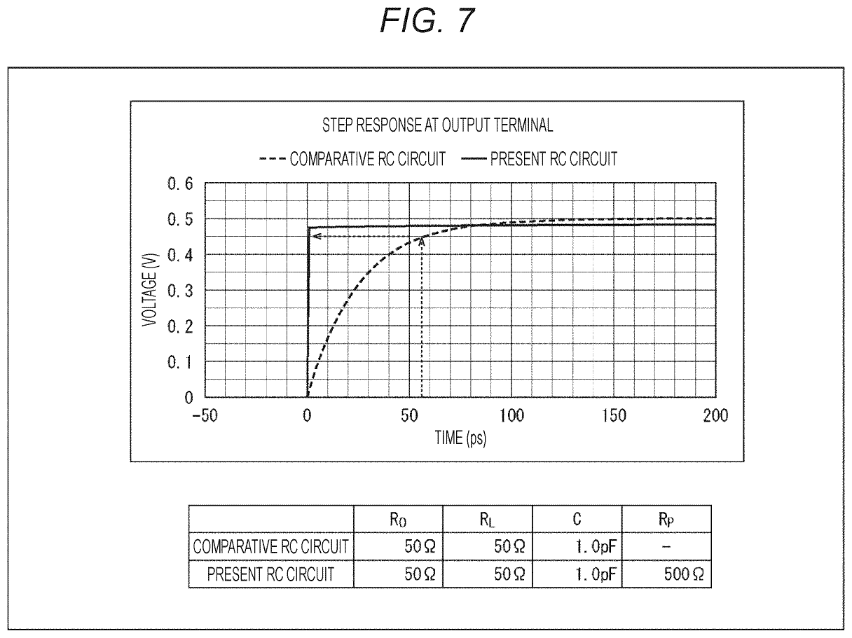

The effect of the wiring structure on the control substrate 42 side, which is connected to the signal pad 51, will be described with reference to FIGS. 6 and 7.

A of FIG. 6 illustrates an RC circuit (hereinafter, referred to as the present RC circuit) corresponding to the present technique of supplying the VSS potential to the shield wiring via the high-resistance element 101, and B of FIG. 6 illustrates an RC circuit as a comparative example (hereinafter, referred to as a comparative RC circuit) without the high-resistance element 101 and the shield wiring of the present technique.

A step response will be considered in a case where a pulse signal changing from 0 V to 1 V is output from a signal source 150 as the output signal SIG.

In the present RC circuit in A of FIG. 6, a resistance 151 functions as wiring resistance of the signal pad wiring 52A or other wirings, a capacitance 152 includes the capacitances 102A and 102B of the shield wiring (wirings 83A and 83B), and a resistance 153 corresponds to the high-resistance element 101. A resistance 155 is the termination resistance. A voltage waveform V_{M1} of an output terminal 154 in the present RC circuit can be represented as the circuit formula illustrated in FIG. 6.

In the comparative RC circuit in B of FIG. 6, a resistance 151′ functions as wiring resistance of the signal pad wiring 52A or other wirings, and a capacitance 152′ corresponds to the parasitic capacitance 103 generated between the signal pad wiring 52A and the wirings 83. A resistance 155 is the termination resistance. A voltage waveform V_{M2} of an output terminal 154 in the comparative RC circuit can be represented as the circuit formula illustrated in FIG. 6.

In the present RC circuit and the comparative RC circuit, conditions other than the resistance 153 corresponding to the high-resistance element 101 are the same. For example, as illustrated in FIG. 7, a resistance value R₀ of the resistance 151 is set to 50Ω, capacitances C of the capacitances 152 and 152′ are set to 1.0 pF, and a resistance value R_{L} of the resistance 155 serving as the termination resistance is set to 50Ω. A resistance value Rₚ of the resistance 153 is set to 500Ω.

FIG. 7 illustrates signal waveforms output from the individual output terminals 154 of the present RC circuit and the comparative RC circuit.

As is apparent with reference to FIG. 7, according to the present RC circuit, the transition time is significantly shortened as compared with the comparative RC circuit. This indicates that the addition of the resistance 153 has made an effective capacitance component small like a low-pass filter in a frequency band for high-speed interface communication. With this arrangement, the data rate can be increased, and the high-speed communication interface can be achieved. The resistance value Rₚ of the high-resistance element 101 corresponding to the resistance 153 is appropriately set according to the communication frequency of the high-speed interface.

As described above, according to the wiring structure on the control substrate 42 side as illustrated in FIGS. 4 and 5, a high resistance can be intentionally generated by using the high-resistance element 101 to reduce the influence of the capacitance on the electrical characteristics, thereby achieving a high-speed communication interface and a broadband.

### <6. Wiring Pattern Examples of Pad Connection Wiring on Control Substrate Side>

As described above, as long as the current value of the output signal SIG is allowed for the signal pad wiring 52A on the control substrate 42 side, the pattern shapes are not required to be uniform, and it is sufficient to form the signal pad wiring 52A in a planar shape suitable for each application. It is sufficient to determine the wiring pattern (planar shape) of the signal pad wiring 52A according to the impedance allowed for connection to the signal pad 51 of the pixel substrate 41 or other components.

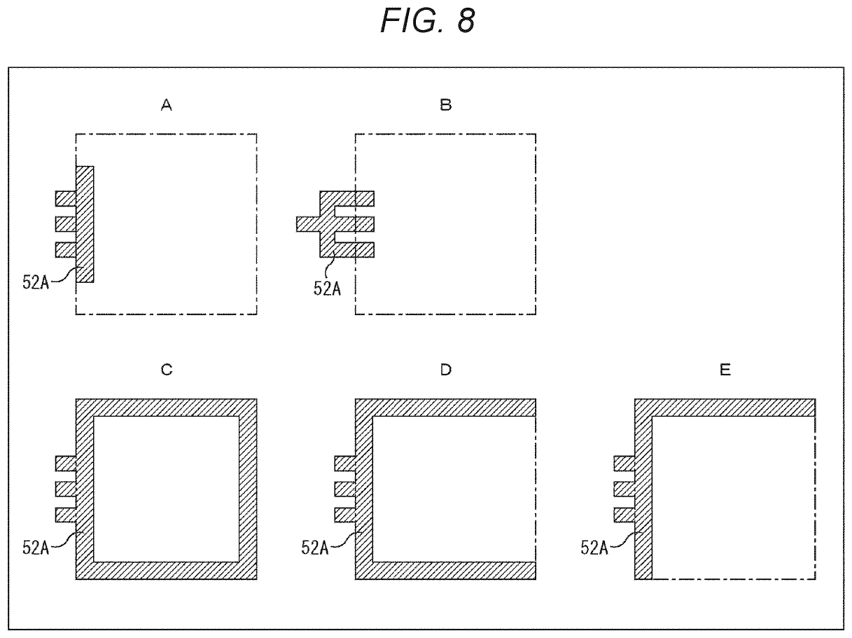

A to E of FIG. 8 illustrate wiring pattern examples of the signal pad wiring 52A. In A to E of FIG. 8, each rectangle shown by one-dot chain line indicates a region where the pad 51 on the pixel substrate 41 side, which is connected to the signal pad wiring 52A, is formed.

A of FIG. 8 is a plan view of the wiring pattern of the signal pad wiring 52A illustrated in FIG. 5. The signal pad wiring 52A includes a three comb-teeth shaped pattern and one linear pattern vertically connected to the three comb-teeth shaped pattern.

B of FIG. 8 is a plan view of another wiring pattern example of the signal pad wiring 52A. The signal pad wiring 52A in B of FIG. 8 includes a three comb-teeth shaped pattern.

C of FIG. 8 is a plan view of another wiring pattern example of the signal pad wiring 52A. The signal pad wiring 52A in C of FIG. 8 includes a pattern with three straight lines and a rectangular pattern with a predetermined line width, which is formed at a position along the outer periphery of the rectangular pad 51 on the pixel substrate 41 side.

D of FIG. 8 is a plan view of another wiring pattern example of the signal pad wiring 52A. The signal pad wiring 52A in D of FIG. 8 includes a pattern with three straight lines and a U-shaped pattern with a predetermined line width, which is formed at a position along the three sides of the rectangular pad 51 on the pixel substrate 41 side.

E of FIG. 8 is a plan view of another wiring pattern example of the signal pad wiring 52A. The signal pad wiring 52A in E of FIG. 8 includes a pattern with three straight lines and a L-shaped pattern with a predetermined line width, which is formed at a position along the two sides of the rectangular pad 51 on the pixel substrate 41 side.

The wiring pattern of the signal pad wiring 52A may also have a pattern shape other than the examples illustrated in A to E of FIG. 8.

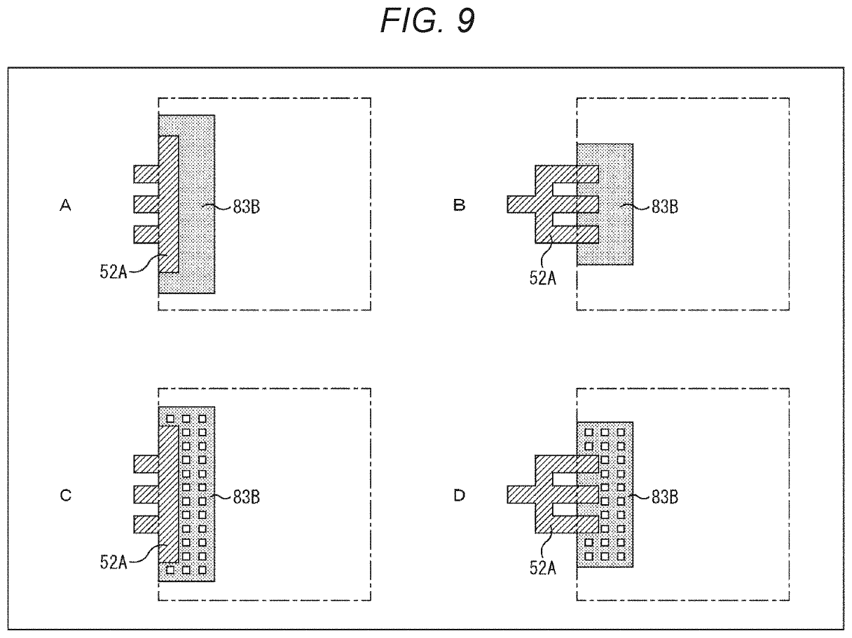

A to D of FIG. 9 illustrate wiring pattern examples of the wiring 83B disposed below the signal pad wiring 52A to which the output signal SIG is input. In A to D of FIG. 9, the wiring pattern of the signal pad wiring 52A is also illustrated in an overlapping manner, and the wiring pattern of A or B of FIG. 8 is employed as the wiring pattern of the signal pad wiring 52A. In A to D of FIG. 9, each rectangle shown by one-dot chain line indicates a region where the pad 51 on the pixel substrate 41 side is formed.

The wiring pattern of the wiring 83B disposed below the signal pad wiring 52A can include solid film patterns as illustrated in A and B of FIG. 9, mesh patterns (lattice-shaped patterns) as illustrated in C and D of FIG. 9, and other patterns. In A and B of FIG. 9, the pattern areas of the wiring 83B are different from each other. Similarly, in C and D of FIG. 9, the pattern areas of the wiring 83B are different from each other. The wiring pattern of the wiring 83B for determining the potential of the capacitance 102B is appropriately determined according to the communication frequency of the output signal SIG.

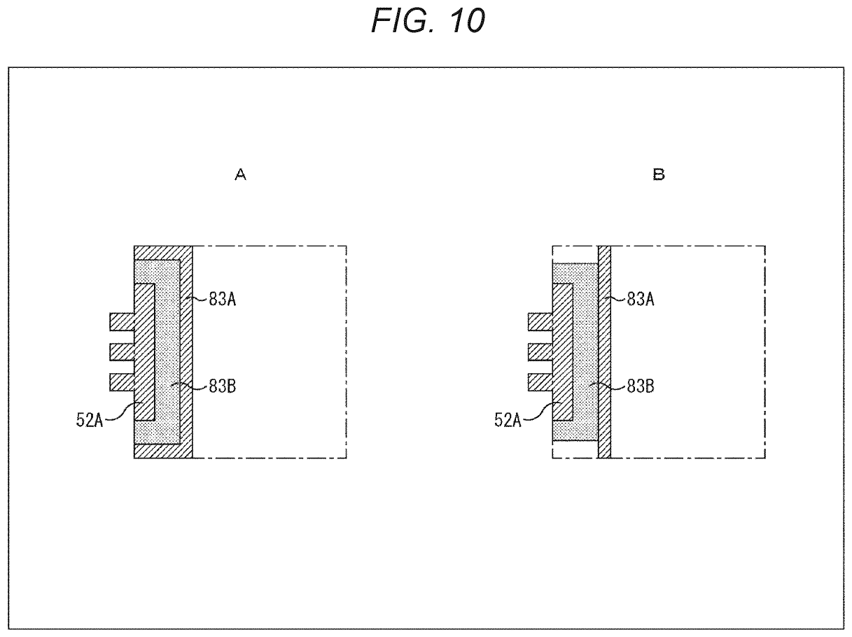

A and B of FIG. 10 illustrate wiring pattern examples of the wiring 83A disposed at the same layer level as the signal pad wiring 52A to which the output signal SIG is input. A and B of FIG. 10 also illustrate wiring patterns of the signal pad wiring 52A and the wiring 83B below the signal pad wiring 52A. In this example, the example in which the wiring pattern illustrated in A of FIG. 9 is employed as the wiring patterns of the signal pad wiring 52A and the wiring 83B is illustrated, but it goes without saying that other wiring patterns may be employed. In A and B of FIG. 10, each rectangle shown by one-dot chain line indicates a region where the pad 51 on the pixel substrate 41 side is formed.

The wiring pattern of the wiring 83A can have a pattern shape surrounding the signal pad wiring 52A to which the output signal SIG is input from three sides in the horizontal direction and the vertical direction as a U-shaped pattern as illustrated in A of FIG. 10.

Alternatively, in a case where a distance from another pad adjacent in the vertical direction in FIG. 10 is sufficiently large, an I-shaped (linear) pattern as illustrated in B of FIG. 10 may be adopted. The wiring pattern of the wiring 83A for determining the potential of the capacitance 102A is appropriately determined according to a communication frequency of the output signal SIG.

FIG. 8 illustrates the wiring pattern examples of the signal pad wiring 52A, FIG. 9 illustrates the wiring pattern examples of the wiring 83B below the signal pad wiring 52A, and FIG. 10 illustrates the wiring pattern examples of the wiring 83A at the same layer level as the signal pad wiring 52A. Any combinations of the wiring patterns of the signal pad wiring 52A, the wiring 83A, and the wiring 83B can be selected, and pattern shapes other than the illustrated patterns may be employed.

In the above-described example, the example in which both the wiring 83A and the wiring 83B serving as the shield wiring are disposed around the signal pad wiring 52A to which the output signal SIG is input has been exemplified, but one of the wiring 83A at the same layer level as the signal pad wiring 52A or the wiring 83B below the signal pad wiring 52A may also be used.

### <7. Wiring Pattern Examples of Pad Connection Wiring for Power-Supply Voltage and Ground>

In the description so far, the wiring pattern examples of the signal pad wiring 52A for signal application such as a pixel signal and a control signal, and the wiring 83A and the wiring 83B formed around the signal pad wiring 52A have been described. Meanwhile, as described with reference to FIG. 2, the pad wirings 52 connected to the pads 51 of the pixel substrate 41 include the power supply or ground pad wiring 52B in addition to the signal pad wiring 52A.

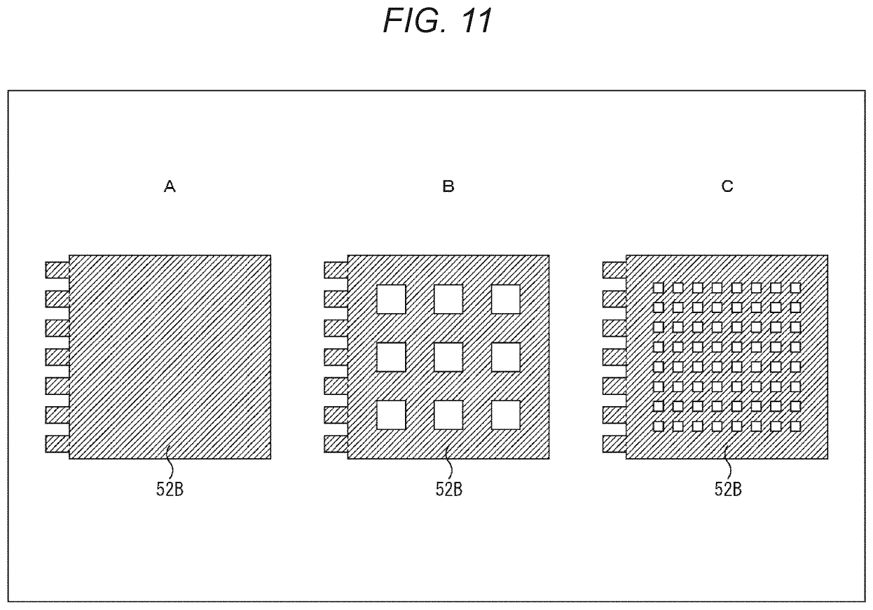

A to C of FIG. 11 illustrate wiring pattern examples of the power supply or ground pad wiring 52B. In A to C of FIG. 11, each rectangle shown by one-dot chain line (the edges of the rectangle and one-dot chain line are almost overlapped with each other) indicates a region where the pad 51 on the pixel substrate 41 side is formed.

The power supply or ground pad wiring 52B is formed to have a high pattern density so as to have a low impedance because the power supply or ground pad wiring 52B is required to allow a sufficient current to flow. For example, as illustrated in A of FIG. 11, the power supply or ground pad wiring 52B is formed in a rectangular pattern having the same size as the pad 51 on the pixel substrate 41 side. Alternatively, the power supply or ground pad wiring 52B may be formed in a mesh pattern having a thick line width as illustrated in B of FIG. 11 or a mesh pattern having a thin line width but a large number of lines as illustrated in C of FIG. 11. Pattern shapes other than the wiring patterns illustrated in A to C of FIG. 11 may be employed. The wiring patterns of the power supply or ground pad wiring 52B are formed as a larger plane area and pattern density than those of the signal pad wiring 52A for signal application.

### <8. Configuration Example of High-Resistance Element>

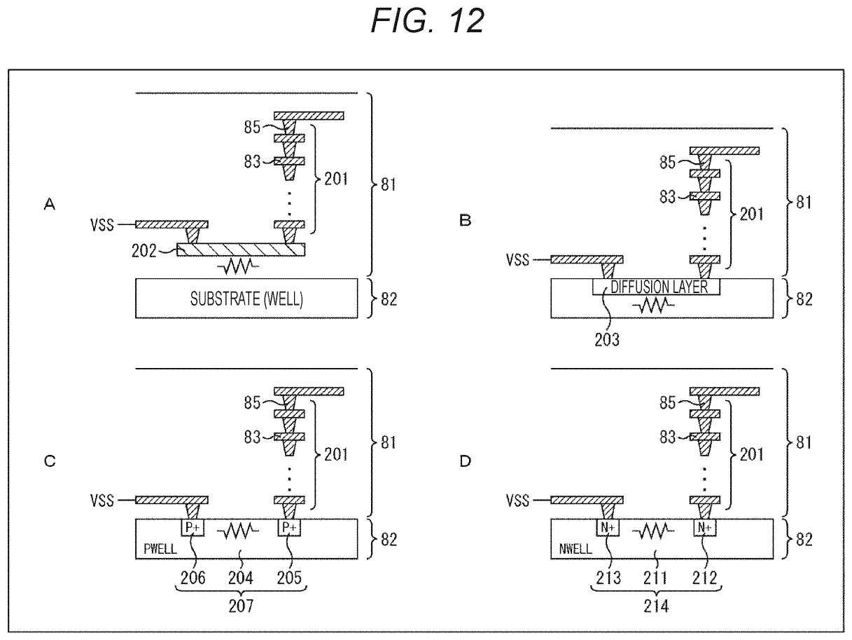

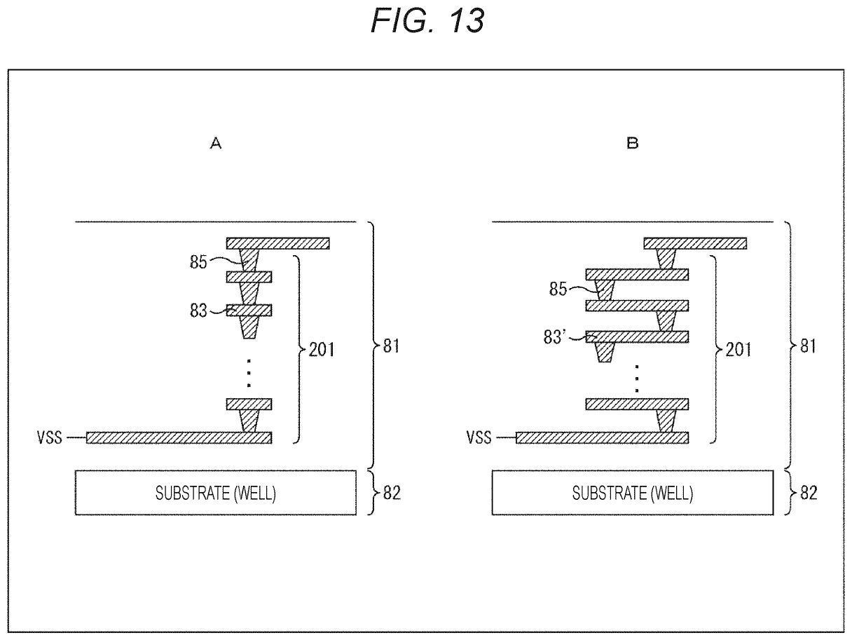

Next, configuration examples of the high-resistance element 101 connected to the wirings 83A and 83B serving as the shield wiring will be described with reference to FIGS. 12 and 13.

For example, as illustrated in A of FIG. 12, the high-resistance element 101 can include a parasitic resistance caused by a stacked via 201 formed in the wiring layer 81 and a metal resistance 202. The stacked via 201 includes the multi-layer wirings 83 and the via 85 that connects the upper and lower wirings 83, and the number of the layered wirings 83 and the number of the vias 85 can be appropriately determined. A polysilicon resistance formed using polysilicon may be used instead of the metal resistance 202.

In addition, for example, as illustrated in B of FIG. 12, the high-resistance element 101 can include a parasitic resistance caused by the stacked via 201 formed in the wiring layer 81 and a diffusion resistance 203 formed in a diffusion layer of the semiconductor substrate 82.

In addition, for example, as illustrated in C of FIG. 12, the high-resistance element 101 can include a parasitic resistance caused by the stacked via 201 formed in the wiring layer 81, and a P-well resistance 207 including a P-well 204 and P+ layers (high-concentration P-type layers) 205 and 206 of the semiconductor substrate 82.

In addition, for example, as illustrated in D of FIG. 12, the high-resistance element 101 can include a parasitic resistance caused by the stacked via 201 formed in the wiring layer 81, and an N-well resistance 214 including an N-well 211 and N+ layers (high-concentration N-type layers) 212 and 213 of the semiconductor substrate 82.

In addition, for example, as illustrated in A of FIG. 13, the high-resistance element 101 may have a configuration in which a parasitic resistance caused by the stacked via 201 formed in the wiring layer 81 is simply provided. As illustrated in B of FIG. 13, the high-resistance element 101 may have a configuration in which a parasitic resistance is caused by a combination of a thin wiring 83′ and the stacked via 201.

The high-resistance element 101 can be realized with a small area by using the parasitic resistance of the wiring 83 or the via 85.

### <9. Modification of Potential Supplied to Shield Wiring>

In the example described above, the VSS potential (for example, GND) is supplied to the wirings 83A and 83B serving as the shield wiring via the high-resistance element 101.

However, as the potential supplied to the wirings 83A and 83B via the high-resistance element 101, a potential different from the VSS potential may be supplied. More specifically, a Vcom potential (Vcom>VSS) higher than the VSS potential can be supplied to the wirings 83A and 83B via the high-resistance element 101.

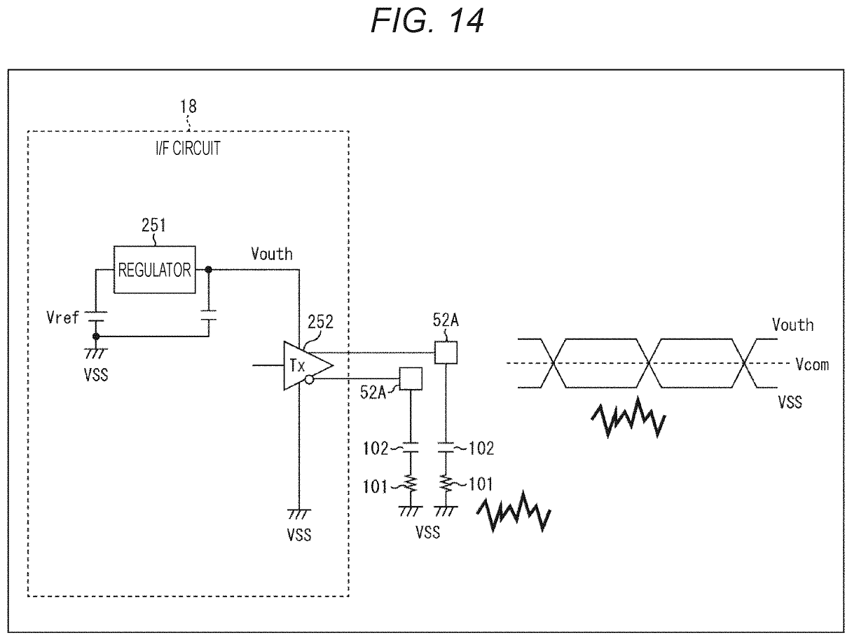

FIG. 14 illustrates the signal pad wiring 52A and the I/F circuit 18 that outputs the output signal SIG in a case where the VSS potential is supplied to the wirings 83A and 83B serving as the shield wiring. Note that, the output signal SIG includes differential signals.

In the I/F circuit 18, a Vouth potential and a VSS potential generated by a regulator 251 are supplied to a driver 252. The driver 252 generates an output signal SIG which includes differential signals with the VSS potential that is an OFF potential and the Vouth potential that is an ON potential, and outputs the output signal SIG to the signal pad wiring 52A. At this time, in a case where noise is included in a well with the VSS potential in the semiconductor substrate 82, the noise of the semiconductor substrate 82 is superimposed on the output signal SIG via the capacitance 102 serving as a pad coupling capacitance to cause jitter.

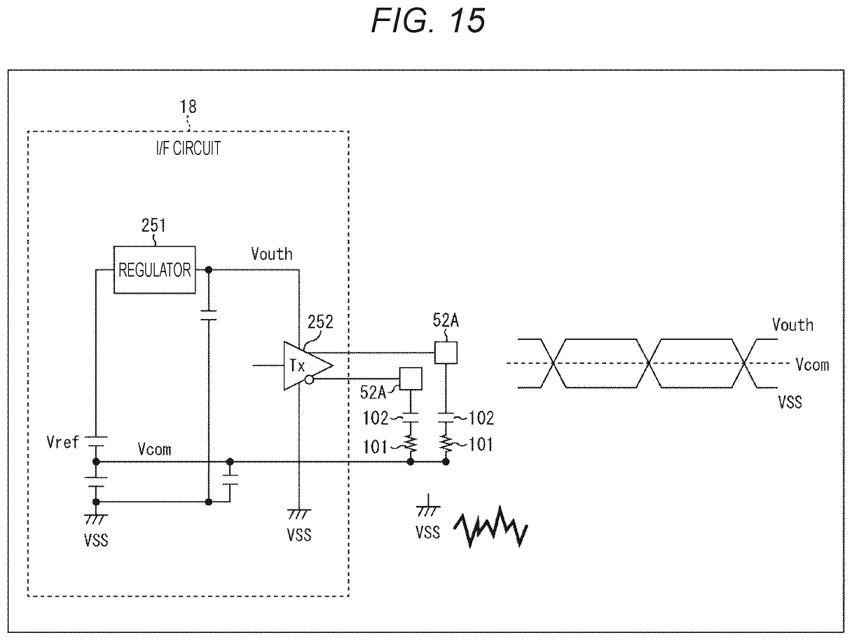

FIG. 15 illustrates the signal pad wiring 52A and the I/F circuit 18 that outputs the output signal SIG in a case where the Vcom potential is supplied to the wirings 83A and 83B serving as the shield wiring.

In a case where the Vcom potential is supplied to the wirings 83A and 83B serving as the shield wiring, the capacitance 102 serving as the pad coupling capacitance is coupled with respect to the Vcom potential even in a case where the noise is included in the well with the VSS potential of the semiconductor substrate 82. Therefore, the noise of the semiconductor substrate 82 is separated and is not superimposed on the output signal SIG to cause jitter.

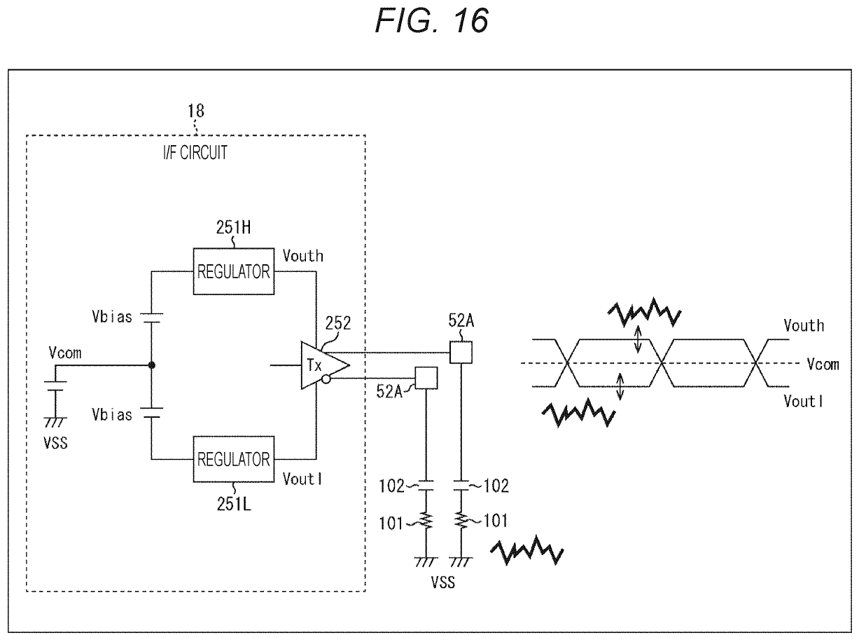

FIG. 16 illustrates the signal pad wiring 52A and the I/F circuit 18 that outputs the output signal SIG in a case where the ON potential and the OFF potential of the output signal SIG are not generated on the basis of the VSS potential but generated on the basis of the Vcom potential.

In the I/F circuit 18, a regulator 251H generates a Vouth potential that is an ON potential and supplies the Vouth potential to the driver 252. A regulator 251L generates a Voutl potential that is an OFF potential and supplies the Voutl potential to the driver 252. The driver 252 generates an output signal SIG which includes differential signals with a Voutl potential that is an OFF potential and a Vouth potential that is an ON potential, and outputs the output signal SIG to the signal pad wiring 52A. In a case where noise is included in the well with the VSS potential in the semiconductor substrate 82, the noise is superimposed on the output signal SIG as jitter because the noise is not in the same phase as the variation of the output signal SIG.

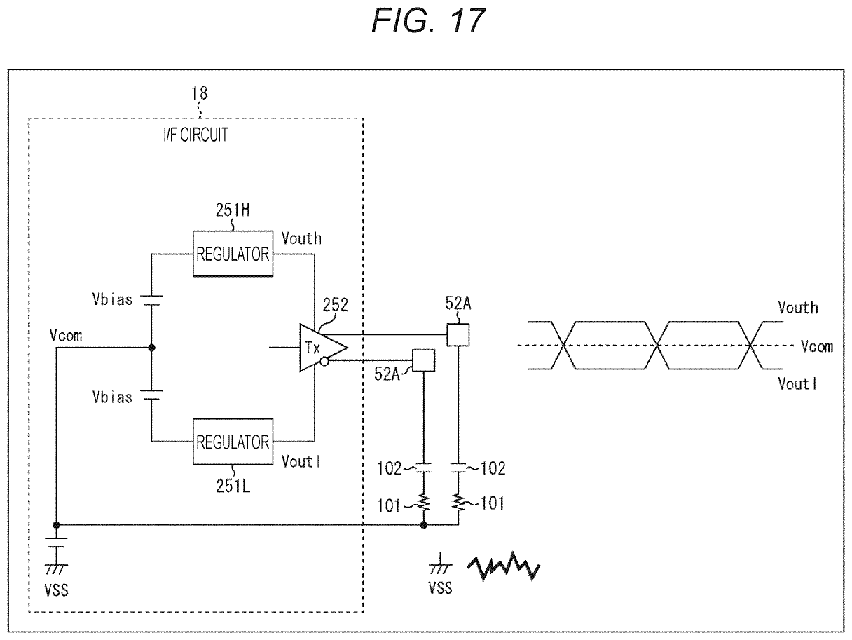

FIG. 17 illustrates the signal pad wiring 52A and the I/F circuit 18 that outputs the output signal SIG in a case where the ON potential and the OFF potential of the output signal SIG are generated on the basis of the Vcom potential, and the Vcom potential is supplied to the wirings 83A and 83B serving as the shield wiring.

In a case where the output signal SIG is generated on the basis of the Vcom potential, and the Vcom potential is supplied to the wirings 83A and 83B serving as the shield wiring, the capacitance 102 serving as the pad coupling capacitance is coupled with respect to the Vcom potential even in a case where the noise is included in the well with the VSS potential of the semiconductor substrate 82. Therefore, the noise of the semiconductor substrate 82 is separated and is not superimposed on the output signal SIG to cause jitter.

As described above, the VSS potential (for example, GND) may be supplied to the wirings 83A and 83B serving as the shield wiring via the high-resistance element 101, but the Vcom potential different from the VSS potential (Vcom>VSS) can be supplied to minimize the VSS noise from being superimposed on the output signal SIG. Since the signal pad wiring 52A is formed as a plane area that is small enough to allow the current value of the output signal SIG, the space in the wiring layer 81 is widened, thereby improving the degree of freedom of the wiring 83. By using this, the Vcom potential different from the VSS potential can be supplied to the wirings 83A and 83B serving as the shield wiring to reduce charge and discharge charges of the pad coupling capacitance.

### <10. Usage Example of Image Sensor>

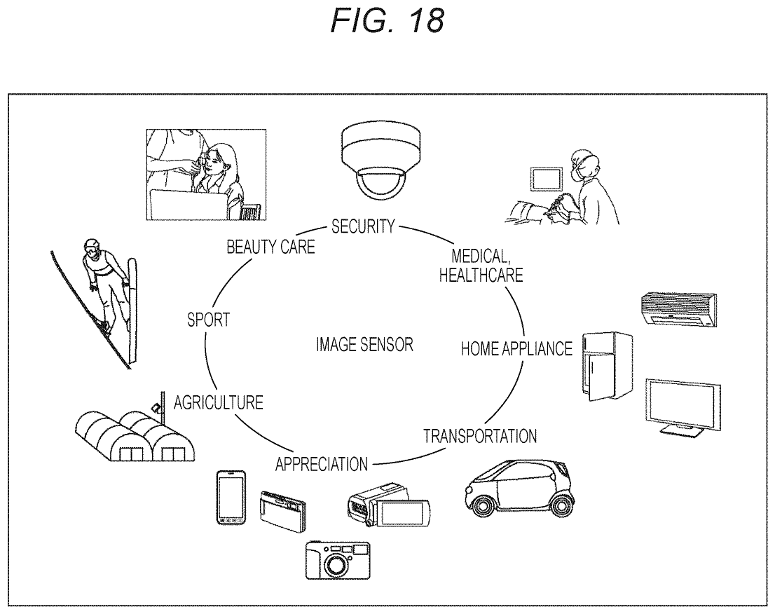

FIG. 18 is a diagram illustrating a usage example of an image sensor using the above-described solid-state imaging device 1.

The above-described solid-state imaging device 1 can be used as an image sensor in various cases of sensing light such as visible light, infrared light, ultraviolet light, and X-rays as described below, for example.
A device that images an image to be used for viewing, such as a digital camera and a portable device with a camera function
A device for traffic purpose such as an in-vehicle sensor which images the front, rear, surroundings, interior and the like of an automobile, a surveillance camera for monitoring traveling vehicles and roads, and a ranging sensor which measures a distance between vehicles and the like for safe driving such as automatic stop, recognition of a driver's condition and the like
A device for home appliance such as a television, a refrigerator, and an air conditioner, which images a user's gesture and performs device operation according to the gesture
A device for medical and health care applications such as an endoscope and a device that performs angiography by receiving infrared light
A device for security use such as a security monitoring camera and an individual authentication camera
A device used for beauty care, such as a skin measuring instrument for imaging skin, and a microscope for imaging the scalp
A device used for sport, such as an action camera or a wearable camera for sports applications and other applications
A device used for agriculture, such as a camera for monitoring a condition of a field or crop

### <11. Application Example for Electronic Device>

Application of the technology of the present disclosure is not limited to that to the solid-state imaging device. That is, the technology of the present disclosure can be applied to general electronic devices using a solid-state imaging device as an image capturing section (a photoelectric conversion section), such as an imaging device such as a digital still camera or a video camera, a mobile terminal device having an imaging function, and a copying machine using a solid-state imaging device as an image reading unit. The solid-state imaging device may be formed as one chip, or may be in a module form having an imaging function in which an imaging section and a signal processing section or an optical system are packaged together.

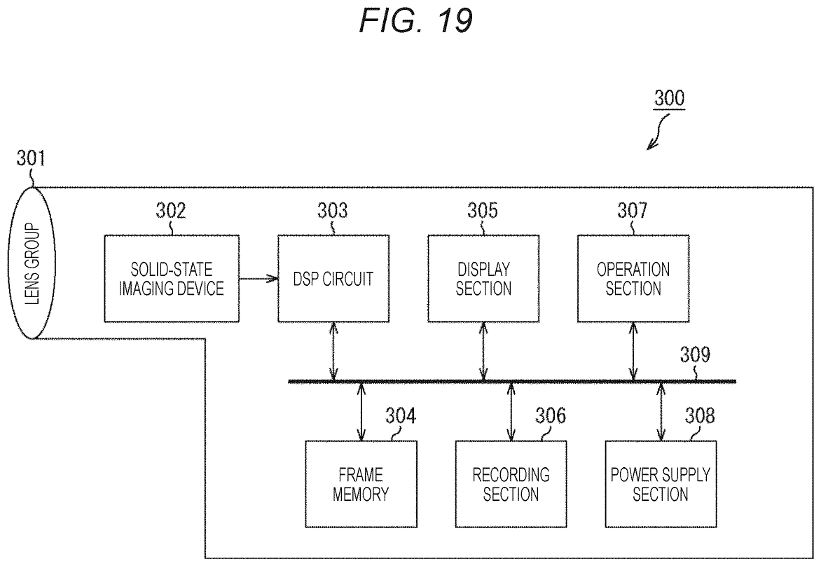

FIG. 19 is a block diagram illustrating a configuration example of an imaging device as an electronic device to which the technology of the present disclosure is applied.

An imaging device 300 in FIG. 19 includes an optical section 301 including a lens group and the like, a solid-state imaging device (imaging device) 302 in which the configuration of the solid-state imaging device 1 in FIG. 1 is employed, and a digital signal processor (DSP) circuit 303 that includes a camera signal processing circuit. In addition, the imaging device 300 also includes a frame memory 304, a display section 305, a recording section 306, an operation section 307, and a power supply section 308. The DSP circuit 303, the frame memory 304, the display section 305, the recording section 306, the operation section 307, and the power supply section 308 are connected to one another via a bus line 309.

The optical section 301 captures incident light (image light) from a subject and forms an image on an imaging surface of the solid-state imaging device 302. The solid-state imaging device 302 converts the light amount of the incident light imaged on the imaging surface by the optical section 301 into an electrical signal in units of pixels and outputs the electrical signal as a pixel signal. As the solid-state imaging device 302, it is possible to use the solid-state imaging device 1 in FIG. 1, that is, the solid-state imaging device in which the shield wiring (wirings 83A or 83B) is disposed around the signal pad wiring 52A on the control substrate 42 side to which the output signal SIG is supplied, thereby supplying a predetermined potential (VSS potential or Vcom potential) via the high-resistance element 101.

The display section 305 includes, for example, a thin display such as a liquid crystal display (LCD), an organic electro luminescence (EL) display, or other displays, and displays a moving image or a still image captured by the solid-state imaging device 302. The recording section 306 records the moving image or the still image captured by the solid-state imaging device 302 on a recording medium such as a hard disk, a semiconductor memory, or other recording medium.

The operation section 307 issues operation commands for various functions of the imaging device 300 under operation by the user. The power supply section 308 appropriately supplies various power sources serving as operation power sources of the DSP circuit 303, the frame memory 304, the display section 305, the recording section 306, and the operation section 307 to these supply targets.

As described above, the configuration of the above-described solid-state imaging device 1 can be employed as the solid-state imaging device 302 to achieve the high-speed communication interface. Therefore, even in the imaging device 300 such as a video camera, a digital still camera, or a camera module for a mobile device such as a mobile phone or other devices, the increased rate of capturing images can be achieved.

### <12. Practical Example for Mobile Body>

The technology according to the present disclosure (present technology) can be applied to various products. For example, the technology of the present disclosure may be achieved in the form of a device to be mounted on a mobile object of any kind, such as an automobile, an electric vehicle, a hybrid electric vehicle, a motorcycle, a bicycle, a personal mobility, an airplane, a drone, a vessel, or a robot.

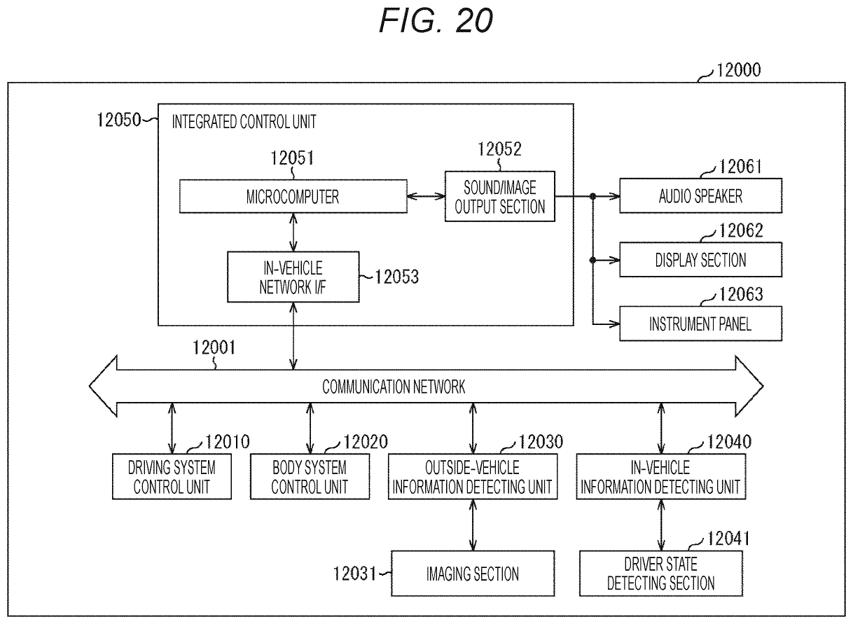

FIG. 20 is a block diagram illustrating a schematic configuration example of a vehicle control system which is an example of a mobile body control system to which the technology according to the present disclosure can be applied.

The vehicle control system 12000 includes a plurality of electronic control units connected to each other via a communication network 12001. In the example illustrated in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, as a functional configuration of the integrated control unit 12050, a microcomputer 12051, a sound/image output section 12052, and an in-vehicle network interface (I/F) 12053 are illustrated.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are exemplified as the output device. The display section 12062 may, for example, include at least one of an on-board display and a head-up display.

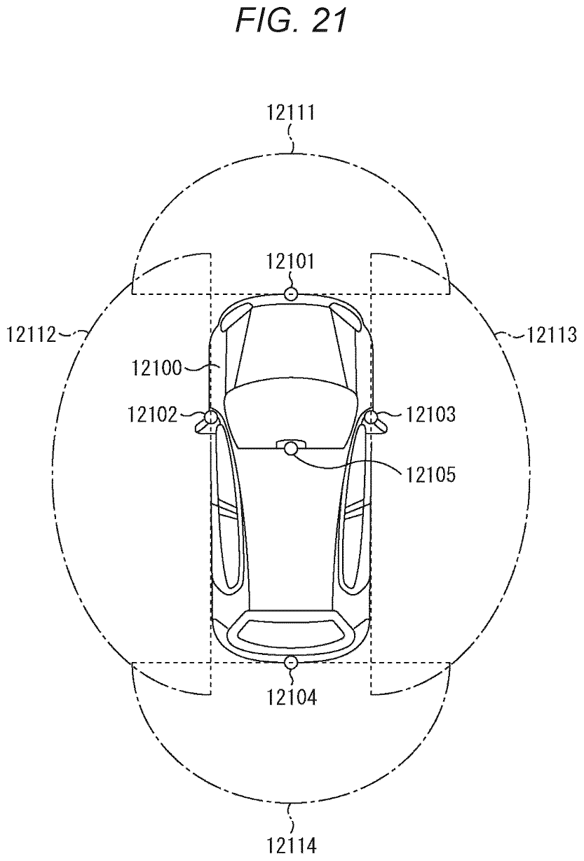

FIG. 21 is a diagram illustrating an example of the installation position of the imaging section 12031.

In FIG. 21, the vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle, and the like. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100.

The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Note that FIG. 21 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure may be applied to the imaging section 12031 in the configuration described above. Specifically, the solid-state imaging device 1 described above can be applied as the imaging section 12031. By applying the technology according to the present disclosure to the imaging section 12031, it is possible to obtain a more easily-viewed imaged image and obtain distance information while achieving the high-speed communication interface. In addition, the obtained imaged image and distance information can be used to reduce driver's fatigue and improve the safety level of the driver and the vehicle.

In addition, the present disclosure is not limited to application to a solid-state imaging device that detects distribution of the amount of incident light of visible light and captures the distribution as an image, and can be applied to all solid-state imaging devices (physical quantity distribution detection devices) such as a solid-state imaging device that captures distribution of the amount of incident infrared rays, X-rays, particles, or the like as an image, and a fingerprint detection sensor that detects distribution of other physical quantities such as pressure and capacitance and captures the distribution as an image in a broad sense.

In addition, the technology of the present disclosure is applicable not only to a solid-state imaging device but also to all semiconductor devices having other semiconductor integrated circuits.

The embodiment of the present disclosure is not limited to the above-described embodiments, and various modifications may be made without departing from the gist of the technology of the present disclosure.

Note that, the effects described in the present specification are merely examples and are not limited, and there may be effects other than those described in the present specification.

Note that, the technology of the present disclosure can have the following configurations.

(1)

A solid-state imaging device including: a pixel substrate on which a pixel is formed; and a control substrate, the pixel substrate and the control substrate being stacked,
in which the pixel substrate includes a pad serving as a contact point with an external device, and
the control substrate includes
   a signal pad wiring connected to the pad,
   a shield wiring disposed around the signal pad wiring, and
   a high-resistance element connected to the shield wiring.

(2)

The solid-state imaging device according to (1),
in which a predetermined potential is supplied to the shield wiring via the high-resistance element.

(3)

The solid-state imaging device according to (2),
in which the predetermined potential includes a VSS potential.

(4)

The solid-state imaging device according to (2),
in which the predetermined potential includes a higher potential than a VSS potential.

(5)

The solid-state imaging device according to any one of (1) to (4),
in which the shield wiring is disposed on at least one position at a same layer level as or below the signal pad wiring.

(6)

The solid-state imaging device according to any one of (1) to (5),
in which the high-resistance element includes a metal resistance or a polysilicon resistance.

(7)

The solid-state imaging device according to any one of (1) to (5),
in which the high-resistance element includes a diffusion resistance.

(8)

The solid-state imaging device according to any one of (1) to (5),
in which the high-resistance element includes a well resistance.

(9)

The solid-state imaging device according to any one of (1) to (8),
in which the high-resistance element includes a parasitic resistance caused by a stacked via.

(10)

The solid-state imaging device according to any one of (1) to (8),
in which the high-resistance element includes a parasitic resistance caused by a stacked via and a thin wiring line.

(11)

The solid-state imaging device according to any one of (1) to (10),
in which the signal pad wiring has a smaller plane area than the pad.

(12)

The solid-state imaging device according to any one of (1) to (11),
in which the pad includes a first pad that outputs a pixel signal of the pixel and a second pad to which a power-supply voltage or a ground is supplied.

(13)

The solid-state imaging device according to (12),
in which the second pad has a larger plane area than the first pad.

(14)

An electronic device including a solid-state imaging device,
in which the solid-state imaging device includes a pixel substrate on which a pixel is formed, and a control substrate, the pixel substrate and the control substrate being stacked,
the pixel substrate includes a pad serving as a contact point with an external device, and
the control substrate includes
   a signal pad wiring line connected to the pad,
   a shield wiring disposed around the signal pad wiring, and
   a high-resistance element connected to the shield wiring line.

### REFERENCE SIGNS LIST

1 Solid-state imaging device
18 I/F circuit
21 Pixel
41 Pixel substrate
42 Control substrate
51 Pad
52 Pad wiring
52A Pad wiring
52B Pad wiring
62 Semiconductor substrate
71 Through-hole
72 Pad
73 Via
81 Wiring layer
82 Semiconductor substrate
83, 83A, 83B, 83C wiring
84 Interlayer insulating film
85, 85A, 85B Via
101 High-resistance element
102, 102A, 102B Capacitance
103 Parasitic capacitance
111 Well region
201 Stacked via
202 Metal resistance
203 Diffusion resistance
204 P-well
207 P-well resistance
211 N-well
214 N-well resistance
251 Regulator
251H Regulator
251L Regulator
252 Driver
300 Imaging device
302 Solid-state imaging device

1. A solid-state imaging device, comprising: a pixel substrate on which a pixel is formed; and a control substrate, the pixel substrate and the control substrate being stacked,
wherein the pixel substrate includes a pad serving as a contact point with an external device, and
the control substrate includes
a signal pad wiring connected to the pad,
a shield wiring disposed around the signal pad wiring, and
a high-resistance element connected to the shield wiring.

2. The solid-state imaging device according to claim 1,
wherein a predetermined potential is supplied to the shield wiring via the high-resistance element.

3. The solid-state imaging device according to claim 2,
wherein the predetermined potential includes a VSS potential.

4. The solid-state imaging device according to claim 2,
wherein the predetermined potential includes a higher potential than a VSS potential.

5. The solid-state imaging device according to claim 1,
wherein the shield wiring is disposed on at least one position at a same layer level as or below the signal pad wiring.

6. The solid-state imaging device according to claim 1,
wherein the high-resistance element includes a metal resistance or a polysilicon resistance.

7. The solid-state imaging device according to claim 1,
wherein the high-resistance element includes a diffusion resistance.

8. The solid-state imaging device according to claim 1,
wherein the high-resistance element includes a well resistance.

9. The solid-state imaging device according to claim 1,
wherein the high-resistance element includes a parasitic resistance caused by a stacked via.

10. The solid-state imaging device according to claim 1,
wherein the high-resistance element includes a parasitic resistance caused by a stacked via and a thin wiring.

11. The solid-state imaging device according to claim 1,
wherein the signal pad wiring has a smaller plane area than the pad.

12. The solid-state imaging device according to claim 1,
wherein the pad includes a first pad that outputs a pixel signal of the pixel and a second pad to which a power-supply voltage or a ground is supplied.

13. The solid-state imaging device according to claim 12,
wherein the second pad has a larger plane area than the first pad.

14. An electronic device, comprising: a solid-state imaging device,
wherein the solid-state imaging device includes a pixel substrate on which a pixel is formed, and a control substrate, the pixel substrate and the control substrate being stacked,
the pixel substrate includes a pad serving as a contact point with an external device, and
the control substrate includes
a signal pad wiring connected to the pad,
a shield wiring disposed around the signal pad wiring, and
a high-resistance element connected to the shield wiring.
